(19) United States
(12) Patent Application Publication
(10) Pub. No.: US 2010/0133658 A1
(43) Pub. Date: Jun. 3, 2010

(54) NITRIDE SEMICONDUCTOR COMPONENT LAYER STRUCTURE ON A GROUP IV SUBSTRATE SURFACE

(76) Inventors: Armin Dadgar, Berlin (DE); Alois Krost, Berlin (DE)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(21) Appl. No.: 12/451,151

(22) PCT Filed: Apr. 28, 2008
(86) PCT No.: PCT/EP2008/055181

§ 371 Date: Feb. 1, 2010

Related U.S. Application Data
(60) Provisional application No. 60/926,444, filed on Apr. 27, 2007.

(30) Foreign Application Priority Data
Apr. 27, 2007 (DE) 10 2007 020 979.9

(51) Int. Cl. H01L 29/20; H01L 21/20

(52) U.S. Cl. 257/615; 438/507; 438/681; 257/E21.09; 257/E29.089

(57) ABSTRACT

The invention relates to nitride semiconductor component having a Group III nitride layer structure which is deposited on a substrate having a Group IV substrate surface made of a Group IV substrate material with a cubical crystal structure. The Group IV substrate surface has an elementary cell with C2 symmetry, but not with a higher rotational symmetry than C2 symmetry, when any surface reconstruction is ignored. The Group III nitride layer structure has a seeding layer of ternary or quaternary Al_{1-x-y}InₓGa_{y}N, where 0≦x, y<1 and x+y≦1, immediately adjacent to the Group IV substrate surface. High-quality monocrystalline growth is achieved as a result. The advantage of the invention consists in the high level of crystal quality that can be achieved, in the growth of c-, a- and m-plane GaN and above all in the ease with which the silicon substrate can be wholly or partially removed, since this is easier to do in a wet chemical process than on (111)-oriented substrates.

### CROSS REFERENCE TO RELATED APPLICATIONS

This application is for entry into the U.S. national phase under §371 for International Application No. PCT/EP2008/055181 having an international filing date of Apr. 28, 2008, and from which priority is claimed under all applicable sections of Title 35 of the United States Code including, but not limited to, Sections 120, 363 and 365(c), and which in turn claims priority under 35 USC §119 to German Patent Application No. 10 2007 020 979.9 filed on Apr. 27, 2007, and U.S. Provisional Patent Application No. 60/926,444 filed on Apr. 27, 2007.

### BACKGROUND OF THE INVENTION

1. Technical Field

The present invention relates to a nitride semiconductor component having a Group III nitride layer structure on a Group IV substrate surface such as silicon, germanium, diamond or a mixed crystal within this system of Group IV semiconductors.

2. Discussion of Related Art

C-axis oriented gallium nitride GaN, grown epitaxially on a silicon substrate having a (111) substrate surface, is currently the prior art and is commercially available.

More recent developments also permit epitaxial growth on a silicon (100) substrate surface, but with poorer crystal quality. Using a silicon (100) surface as the substrate surface for a Group III nitride layer structure for applications in microelectronics is interesting because this can facilitate the integration of GaN-based components in silicon electronics, for example.

It should also be assumed—as is commonplace among experts—that whenever mention is made of growth on a substrate surface, that such growth is or was epitaxial in nature. As is known, an epitaxially deposited layer adopts the lattice structure of the substrate on which it grows, or orients itself according to the symmetry predefined by it, and depending on the lattice mismatch will also adopt the lattice constants, even on monolayers up to microns in thickness. In the following, therefore, the word “epitaxial(ly)” is not necessarily given additional mention when reference is being made to growth on a substrate surface. Known non-epitaxial deposition processes, such as sputtering, result in amorphous or polycrystalline, at best textured layers which are not monocrystalline, and which are unsuitable for optoelectronic components complying with present-day standards.

Growing Group III nitrides on germanium and diamond has been the subject of isolated reports and likewise provides some advantages for certain applications of nitride semiconductor components. These advantages include, for example, the absence of “meltback etching”, and in the case of diamond an unprecedentedly high level of thermal conductivity. The disadvantage of diamond and indeed of germanium as substrate materials is generally their significantly higher price in comparison to silicon, as well as a lower melting point below 1000° C. in the case of germanium.

The quality of the Group III nitride semiconductor layer produced on silicon (111) and in particular on silicon (001) is generally not as good as that on the sapphire or SiC substrates with hexagonal crystal structure that are still used in large measure. One reason for this lower quality is the worse lattice matching of GaN crystallites or of AlN crystallites used as a nucleation layer, in particular their “twist” on the silicon surface. This mostly results in an edge dislocation density in excess of 10⁹ cm⁻², even after 1 μm of layer growth.

Producing thin-film components, such as high-efficiency LEDs, FETs or MEMS on Si(100) is difficult to achieve on account of the poor crystal quality, and on Si(111) due to the difficulties in removing the substrate by etching, just as it is difficult, for example, to etch out small structures by local etching of the silicon for sensor applications. Wet chemical etching of the crystal face on Si(111) is possible only with very aggressive solutions, based for example on concentrated HF and concentrated HNO₃, which in the case of thin-film applications makes it much more difficult to handle and protect the transfer substrate and the transfer layer.

The stated problems can be solved according to a first aspect of the invention by a nitride semiconductor component having a Group III nitride layer structure which is deposited epitaxially on a substrate having a Group IV substrate surface made of a cubical Group IV substrate material, wherein the Group IV substrate surface has an elementary cell with C2 symmetry if any surface reconstruction is ignored, but having a higher rotational symmetry than C2 symmetry, wherein immediately adjacent to the Group IV substrate surface the Group III nitride layer structure has a seeding layer made of either GaN or AlN or of a ternary or quarternary Al_{1-x-y}InₓGa_{y}N, where 0≦x, y<1 and x+y≧1. Thus, in the latter case, the seeding layer is produced from AlInGaN, AlInN, InGaN or AlGaN.

A nitride semiconductor component refers here to a semiconductor component that has a Group III nitride layer structure. A Group III nitride layer structure is a layer structure which in different embodiments contains either one Group III nitride layer or many Group III nitride layers. Hence, in one embodiment, the Group III nitride layer structure may consist of a single Group III nitride layer. A Group III nitride layer is a layer of material made of a compound which contains at least one Group III element and nitrogen. In addition to nitrogen, other Group V elements may be present in such amounts that nitrogen accounts for at least 50% of the Group V atoms in the material. The ratio of atoms of Group III elements to atoms of Group V elements is 1:1 in Group III nitrides. Admixing Group V elements other than nitrogen may be useful for further reducing the lattice mismatch, but may also be exclusively attributable to the requirements of a particular application of the nitride semiconductor components.

A Group IV substrate surface is a substrate surface that is formed by a Group IV substrate material, i.e. by a material which is made of one or more Group IV elements and which forms the substrate surface. A Group IV substrate material thus belong to the system C_{1-x-y}SiₓGe_{y}, where 0≦x, y≦1 and x+y≦1. In the nitride semiconductor component, the Group IV substrate surface forms a boundary surface, assumed for definition purposes as being ideal, between the Group IV material and the Group III nitride layer structure. The Group IV substrate surface may be the surface of a wafers made of Group IV material, or the surface of a thin layer, for example on an alien substrate or on a SOI-type (silicon-on-insulator-type) substrate.

C2 symmetry belongs to the family of finite cyclic symmetry groups in the Euclidian plane. It forms a discrete symmetry group, the symmetry operations of which do not include any displacements or any reflections about an axis, but which do include rotations about a point by multiples of 180°. The Group IV substrate surface, in other words, is characterised by a substrate surface formed by elementary cells of Group IV atoms, wherein one elementary cell repeats or reproduces itself on any rotation by 360 degrees divided by two—i.e. by 180 degrees and by any multiple thereof. For this reason, C2 symmetry is also referred to as twofold symmetry. An elementary cell with C2 symmetry and without any higher rotational symmetry has (trivial) single symmetry, i.e. C1 symmetry, and twofold, i.e. C2 symmetry, but not any rotational symmetry of higher order, i.e. no C3 or C4 symmetry, for example. C1, as is known, is the symmetry group of a completely asymmetrical object having the identity of a single element.

For the purpose of defining concepts in the context of the present description and the claims, any surface reconstruction is ignored when determining the symmetry of the elementary cell of the Group IV substrate surface. This means, in particular, that in a hypothetical cross-section in a plane parallel to its substrate surface, the Group IV substrate surface has an elementary cell with C2 symmetry, but not with a higher rotational symmetry than C2 symmetry. In order to simplify the wording of this application, such a substrate surface is also referred to as a surface with (only) twofold symmetry.

With regard to notation, it should be noted that standard (round) parentheses are used to denote a specific crystal orientation of a substrate surface, for example: Si(100). Curly brackets are used to denote a group of orientations of a substrate surface that are equivalent. Hence, the notation Si{110} surface denotes all surfaces of Si that are equivalent to the Si(100) surface. Simple square brackets are used to denote direction, for example the [110] direction which is in a plane perpendicular to the (110) surface. Angle brackets denote a group of equivalent directions, for example the group of <110> directions that also include the [110] direction.

Group IV substrate surfaces comprising an elementary cell with C2 symmetry, but without any rotational symmetry of a higher order than C2 symmetry, have the advantage that they have especially high lattice matching with Group III nitrides and thus permit the monocrystalline epitaxial deposition of a Group III nitride layer structure of especially high crystallographic quality. This reduces the defect density in the Group III nitride layer structure, as a result of which the performance and useful life of the nitride semiconductor component can be improved.

In addition, the use of C_{1-x-y}SiₓGe_{y} (0≦x, y≦1, x+y≦1) surfaces having only twofold symmetry has the essential additional advantage that wet chemical etching is made easier. This makes it easier to remove nitride semiconductor component layers that are glued to substrates and which are to be further processed as ultrathin layers. When silicon is used, using surfaces having only twofold symmetry therefore obviates the costly need to protect, with acid-resistant substances, the layer promoting adhesion to the new substrate, which layer frequently comprises metal layers such as Au/Sn.

From this aspect, the nitride semiconductor component for which protection is claimed may form an intermediate product for an ultrathin nitride semiconductor component, in which the substrate containing the Group IV substrate material onto which the Group III nitride layer structure is disposed is removed in a later step of the process.

The following description mostly contains examples in which silicon is used as the substrate material. However, this is not to be understood as limiting the applicability of the invention. In respect of the substrate material used, the invention may be applied to the entire system comprising C_{1-x-y}SiₓGe_{y}, where 0≦x, y≦1 and x+y≦1. As is known, the lattice parameters of the crystal lattice in the substrate surface are different when Group IV substrate materials other than silicon are used.

A particular set of lattice parameters does not provide equally favourable lattice matching for all Group III nitrides. For this reason, different Group IV materials with one or more of their different substrate surfaces having at most twofold symmetry may be suitable for different Group III nitride layer structures. According to the invention, the Group III nitride layer structure of the nitride semiconductor component has an Al_{1-x-y}InₓGa_{y}N seeding layer immediately adjacent to the Group IV substrate surface. Here, 0≦x, y≦1 and x+y≦1. Due to different lattice parameters, either binary or ternary or quaternary material may be selected for a seeding layer for some Group IV substrate surfaces with twofold symmetry, depending on which is most suitable in the specific case. When compiling suitable combinations of Group IV substrate surfaces and Group III nitride layer structures to be deposited thereon, it is essential to take into account the respective lattice parameters, known per se, of the potential Group IV substrate surfaces, and of the potential Group III nitrides, giving consideration thereby to the required properties of the respective nitride semiconductor component.

Some embodiments of the nitride semiconductor component according to the invention will now be described.

In some embodiments of nitride semiconductor components, either AlN or a Group III nitride of type Al_{1-x-y}InₓGa_{y}N containing a high proportion of Al (at least 80%), indeed in one embodiment close to pure AlN, is used in the Group III nitride layer structure as a seeding layer disposed directly on the Group IV substrate surface. In a large group of different nitride semiconductor components, a low lattice mismatch between the Group IV substrate surface and the seeding layer, as achieved in this manner, is of major importance for the crystal quality of the Group III nitride layer structure. Crystal quality, in turn, affects the performance parameters and the useful life of (opto)electronic components.

For the example of an Si(100) surface, AlN is a suitable material for a seeding layer. The lattice matching of the Si(100) surface to GaN is also good, however. A GaN seeding layer is also suitable, therefore. The lattice mismatch in this case is approximately 2% in the direction that also has a low mismatch in the case of AlN, and approximately 16.9% in the other direction.

When using MOVPE (metal organic vapour phase epitaxy), undesired meltback etching may occur when a growing Group III nitride layer contains a higher proportion of gallium. “Meltback etching” refers to a reaction of the gallium in a growing Group III nitride layer with the silicon of the substrate material. When the substrate material is silicon, and especially when using MOVPE to prevent meltback etching, the Al weight ratio among the Group III elements in the seeding layer is therefore 90% or more in relation to the total number of Group III atoms, and the weight ratio of gallium is accordingly 10% at most.

In one embodiment, an alloy of Si with Ge is present as the as the Group IV substrate material. This substrate material permits deposition with a low likelihood of meltback etching occurring. An appropriately selected Si—Ge alloy can also permit particularly good lattice matching of a GaN seeding layer.

Using diamond or Ge as the substrate materials also prevents meltback etching.

In one embodiment, the Group IV substrate surface is an Si(100) surface. In one direction, this surface has a very low lattice mismatch with the c-axis oriented and m-plane AlN, thus allowing better orientation of the layers of the Group III nitride layer structure on the substrate. Group IV substrate materials with other Group IV {110} substrate surfaces may also be used, with similarly favourable characteristics in respect of the lattice mismatch with AlN.

Substrates with a Si(100) substrate surface also have the advantage that they are commercially obtainable in large quantities and can therefore be procured easily and at low cost.

As an alternative to the {110} substrate surfaces, other Group IV substrate surfaces with twofold symmetry and hence with similar symmetry may be used. The {120} Group IV substrate surfaces for forming other embodiments, as well as other {nm0}-type surfaces with a higher index, where n, m are non-zero integers, are likewise of interest, therefore, not only for growing high-quality Group III nitride layer structures, but also for growing a single high-quality Group III nitride layer, such as a GaN layer. These are {nml}-type surfaces, where n, m, are non-zero integers, and l≧2.

According to a second aspect of the invention, a process for producing a nitride semiconductor component comprises epitaxial deposition of a Group III nitride layer structure onto a Group IV substrate surface made of a Group IV substrate material with a cubical crystal structure, wherein the Group III nitride layer structure is deposited epitaxially on a Group IV substrate surface which for the purpose of conceptual definition, ignoring any surface reconstruction, has an elementary cell with C2 symmetry, but not with a higher rotational symmetry than C2 symmetry, and immediately adjacent to the Group IV substrate surface a seeding layer made of either AlN, GaN or of ternary or quaternary Al_{1-x-y}In_{y}Ga_{y}N, 0≦x, y<1 and x+y≦1, is epitaxially deposited.

The advantages of the process according to the invention correspond to those of the nitride semiconductor component according to the first aspect of the invention.

In one embodiment, the process comprises partially or wholly wet or dry chemical removal of the substrate after deposition of the Group III nitride layer structure. This embodiment achieves the realisation of low-cost thin-film technology for nitride semiconductor components.

### BRIEF DESCRIPTION OF THE DRAWINGS

The invention shall now be described on the basis of further embodiments and with reference to the Figures, in which:

FIGS. 1a)-c) show a plan view of a) a silicon (100), b) a silicon (110) and c) a silicon (111) surface, in each case with an AlN covering;

FIG. 2 shows a cross-sectional view of one embodiment of a nitride semiconductor component having a Group III nitride layer structure;

FIGS. 3a)-f) show different phases of an embodiment of a process for producing a nitride semiconductor component.

### DETAILED DESCRIPTION

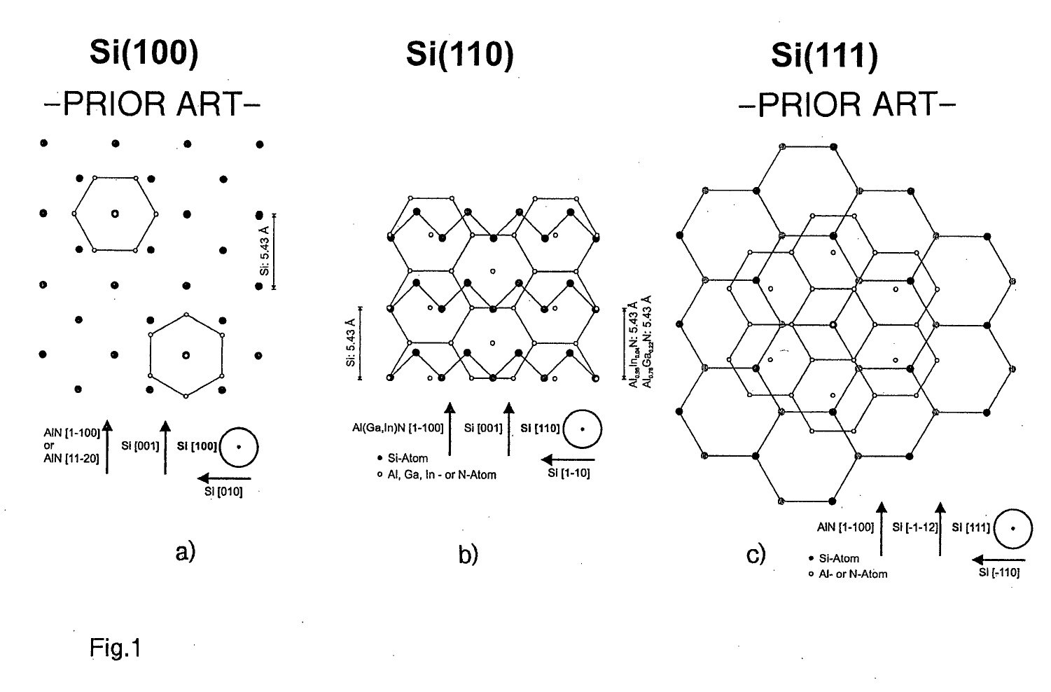

FIG. 1 shows, to explain one embodiment of a nitride semiconductor component and to compare this with solutions from the prior art, a plan view of a Group IV substrate surface in the form of a) a silicon (100), b) a silicon (110) and c) a silicon(111) surface, each having an Al_{1-x-y}InₓGa_{y}N covering, where 0≦x, y<1 and x+y≦1. Only FIG. 1b) is relevant as an embodiment of the invention; the other two FIGS. 1a) and 1c) show, by way of comparison, the structure of substrate surfaces already used in the prior art. The best lattice matching in one direction is obtained when ternary materials are used for Al_{0.97}In_{0.03}N and Al_{0.78}Ga_{0.22}N. Even slight admixing of Ga and In is helpful in improving the material parameters. When a quaternary material is used, the ideal concentrations of In and Ga are correspondingly lower. However, higher concentrations are also possible and may be advantageous, depending on the process, since then the lattice mismatch in the [1-10] direction is also reduced, albeit at the cost of that in the direction perpendicular thereto.

In FIG. 1, filled circles symbolise the position of silicon atoms on the silicon (110) substrate surface, and open circles symbolise the position of either nitrogen or aluminium atoms in the Al_{1-x-y}InₓGa_{y}N covering deposited thereon. In order to simplify the graphic representation, no graphic distinction is made between other Group V elements and Al. However, it should be understood that the example uses a ternary or quaternary alloy. Hence, pure AlN is not in fact meant, but rather a ternary or quaternary seeding layer that in some embodiments contains a high proportion of Al. The expressions “nucleation layer” and “seeding layer” are used synonymously in this application.

In the embodiment in FIG. 1b) under consideration here, the Al_{1-x-y}InₓGa_{y}N covering of the silicon substrate surface forms a seeding layer when a Group III nitride layer structure begins to grow on the substrate surface, as is frequently used for growing GaN.

The following observations are to understood as examples only. Instead of the commonly used Si{110}, on which c-axis oriented AlN is then preferably produced, other combinations of materials could also be used, by way of explanation, for the Group IV substrate surface and the Group III nitride layer structure growing thereon.

The Al atoms are disposed at corners of hexagonal unit cells. The shorter spacings of the edges of a hexagon forming the unit cell of Al_{1-x-y}InₓGa_{y}N extend in the [symbol] 1 1̅00 [symbol] direction. In the non-ideal case of using AlN, these spacings are 5.41 Å and may be reduced, for example with Al_{0.97}In_{0.03}N or Al_{0.78}Ga_{0.22}N, to 5.43 Å, a mismatch of 0%, thus achieving improved layer characteristics compared to the use of an AlN nucleation layer. The shorter spacing of the Si unit cells extends in [symbol] 100 [symbol] directions and amounts to 5.43 Å. The mismatch in the Al(Ga,In)N [symbol] 1 1̅00 [symbol] ∥Si<100> direction when viewing each second lattice plane is therefore 0%, but 0.37% in the case of AlN.

For Al_{0.07}In_{0.03}N and Al_{0.78}Ga_{0.22}N [symbol] 11 2̅0 [symbol] ∥Si<110>, however, it is just under 18-19%, as is also the case for this material on the known substrate surface Si(111). Hence, there is very good lattice matching in one direction on the surface in comparison with other cubical substrate materials without C2 symmetry of the elementary cell. This very good matching in one direction has a positive effect on the crystal quality.

There would appear to be a slight lattice mismatch in relation to the Al(Ga,In)N [symbol] 1 1̅00 [symbol] ∥Si<100> directions for AlN on Si(100), if one were to take into consideration the surface reconstruction (not shown in FIG. 1 a)). However, closer inspection shows that this is not true for larger surface sections. In the case of this silicon surface, an additional difficulty consists in a rotational symmetry of the elementary cell for 90° rotational operations as well, due to the fourfold rotational symmetry (C4) that exists in this silicon surface. The Si(100) surface is initially given a preferred direction by a specific reconstruction, such as the (2×1) reconstruction. However, there is actually no uniform reconstruction on the Si(100) surface. Rather, there are only small surface sections with different reconstructions, 50% of which are (2×1) and 50% of which are (1×2). Under these conditions, therefore, this surface has preferential directions and hence C2 symmetry in small sections at most. These are not suitable for monocrystalline epitaxial growth. The advantages of improved lattice matching can therefore only be achieved on a Group IV substrate surface that, ignoring any surface reconstruction, has an elementary cell with C2 symmetry, but not with a higher rotational symmetry than C2 symmetry.

In such surfaces with only twofold symmetry of the {nm0} or {mnl} type, for example (110), a strongly characteristic zigzag structure of atomic bonds, for example of silicon bonds, forms a preferential direction which produces an unambiguous specification for a twist of the growing Al(Ga,In)N, as shown in FIG. 1. Here, the atoms of the Al(Ga,In)N unit cell are almost always close to a silicon atom and hence to a potential bond. To grow Al(Ga,In)N with an elementary cell twisted 90°, there is mostly only random matching of the Al(Ga,In)N with Si, but this is not regular, and if present, exists only over shorter distances and has fewer bonding possibilities.

On most higher-order surfaces with twofold symmetry, AlN grows likewise with a preferred c-axis orientation.

Although, for a Group IV substrate surface {nml} surface where n, m, are non-zero integers and l≧2, the analogue lattice matching AlN [symbol] 1 1̅00 [symbol] ∥Si<100> is somewhat worse in the case of silicon, it suffices entirely for the deposition of high-quality nitride semiconductor component layers. Excellent smooth nitride semiconductor surfaces are thus obtained for {511}, {711} and {911} surfaces, for example.

In the case of silicon, {410} surfaces are advantageous for the growth of m-plane or a-plane Al(Ga,In)N, since the structure repeats itself every 10.86 Å, which results in very low mismatch values of approx. 7.5% for two Al_{0.97}In_{0.03}N or Al_{0.78}Ga_{0.22}N unit cells in the c-direction (8.6% for AlN) and 0% in the perpendicular direction for m-plane Al(Ga,In)N (0.37% für AlN). For a-plane GaN-rich nucleation layers, a {41l}-type surface where 12 and {114} is especially suitable, because this results in better lattice matching.

If no countermeasures in the form of prestressing are taken during growth, the resultant nitride semiconductor layer will be under tensile strain due to the thermal mismatch of the materials after cooling, and this strain may be slightly anisotropic. This is attributable to the low symmetry of the crystal orientation, which in contrast to the threefold orientation of Si(111) (FIG. 1c) or the fourfold orientation of Si(100) is not isotropic, i.e. is different in the Si<100> and Si<110> directions. Removed layers can therefore be recognised by an anisotropic strain which can be detected with curvature measurements, or even better with X-ray measurements.

In order to etch silicon, there are many options ranging from alkaline KOH to aggressive and very poisonous acid mixtures, such as HF and HNO₃. The former stops on Si{111} surfaces, but the latter do not. For this reason, a Si(111) substrate can be removed by wet chemical measures within a reasonable time by working with the latter etching solution. However, the aggressive components of the latter dissolve many metals, thus making it more difficult to remove nitride semiconductor component layers adhering to substrates and intended for further processing as thin films.

In general, using C_{1-x-y}SiₓGe_{y} (0≦x, y≦1, x+y≦1) has the additional advantage that it can facilitate wet chemical etching. The (111) surface is generally more chemically stable, by comparison, and therefore not as easy to remove in a wet chemical etching step. When silicon is used, using surfaces having only twofold symmetry therefore obviates the costly need to protect, with acid-resistant substances, the layer promoting adhesion to the new substrate, which layer frequently comprises metal layers such as Au/Sn.

The invention is applicable to any nitride semiconductor components with a Group III nitride layer structure. Optical, optoelectronic and electronic components such as LEDs, laser diodes, transistors and MEMS components are to be understood as examples of applications, but the applications of the invention is not limited to these. Their advantage consists in the high level of crystal quality that can be achieved, in the growth of c-, a- and m-plane GaN and in the ease with which the substrate can be wholly or partially removed, since this is easier to do in a wet chemical process than on (111)-oriented substrates.

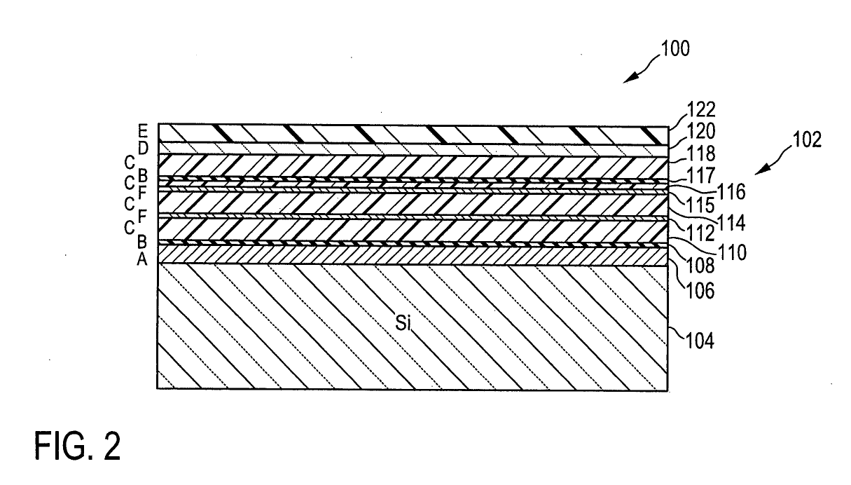

FIG. 2 shows, in a schematic view, the layer structure of a nitride semiconductor component 100. The nitride semiconductor component 100 may form an intermediate product during the production of an ultrathin nitride semiconductor component.

This illustration in FIG. 2 is not true to scale. More specifically, it is not possible to determine the exact ratios among the individual layer thicknesses. The layer thickness ratios shown in the Figure thus provide a very rough indication only. In the following description, aspects of the process will be explained parallel to aspects of the device in order to keep the description concise.

The nitride semiconductor product 100 contains a Group III nitride layer structure 102 on a silicon wafer 104. The growth surface of the wafer being used, which is perpendicular to the plane of FIG. 1, is a (110) silicon surface. An SOI substrate or any other substrate, preferably with a (110) silicon surface, may be used in place of a silicon wafer.

For the sake of clarity, letters A to F are provided to the left of the individual layers in FIG. 2, in addition to the numerical reference signs 106 to 122, in order to label the layers of the Group III nitride layer structure 102. Identical letters designate layers of the same type, where

A shows a ternary or quaternary nitride seeding layer in combination with a buffer layer,
B shows a masking layer,
C shows nitride semiconductor component layers, here specifically n-type GaN layers,
D shows a multi-quantum well structure,
E shows a p-doped nitride semiconductor covering layer, here specifically p-GaN and
F shows a low-temperature AlN or AlGaN interlayer for strain engineering purposes.

Further details of the layer structure and its production shall now be described.

Before layers are deposited, the growth surface of wafer 104 is passivised. This means that it is deoxidised either by wet chemical treatment or by heating in a vacuum or under hydrogen at temperatures above 1000° C., and that a hydrogen-terminated surface is produced.

Seeding layer 106 has a thickness of 10-30 nm. When combined with a buffer layer deposited thereon in the present example, but which is basically optional when performing the process, a maximum layer thickness of 400 nm is obtained.

A Al_{1-x-y}InₓGa_{y}N nucleation layer (also referred to as a seeding layer), 0≦x, y<1 and x+y≦1, grown either at low temperature, i.e. below 1000° C., for example at 600 to 800° C., or at high temperature, i.e. at normal growth temperatures of Al_{1-x-y}InₓGa_{y}N above 1000° C., is suitable for this purpose. The optional buffer layer is preferably likewise of Al_{1-x-y}InₓGa_{y}N or AlN and is applied at high growth temperatures. The buffer layer may also consist of AlGaN. When AlGaN is used, the seeding layer may also have a greater thickness, for example of approximately 600 nm.

When growing the nucleation layer, it is beneficial to start feeding the aluminium precursor into the reactor before feeding the nitrogen precursor, in order to prevent nitridation of the substrate. Nitridation of the substrate can lead to undesired polycrystalline growth, i.e. to non-epitaxial growth.

A masking layer 108 made of silicon nitride is deposited on the seeding and buffer layer composite 106. This deposition is performed by simultaneously introducing a silicon precursor, such as silane or disilane or an organic silicon compound, and a nitrogen precursor, such as ammonia or dimethyl hydrazine. The two precursors react on the growth surface to form silicon nitride.

The thickness of a GaN layer 110 deposited thereon is between 800 and 1600 nm. For strain engineering purposes, a nitride semiconductor interlayer containing aluminium is deposited in the form of an (optional) low-temperature AlN interlayer 112. The low-temperature AlN interlayer has a thickness of 8-15 nm.

Inserting the low-temperature AlN interlayer 112 permits a greater total thickness of the GaN layer to be achieved by growing a sequence of other GaN layers and low-temperature AlN interlayers. The low-temperature AlN interlayer 112 is thus followed by a second GaN layer 114, again of approximately 800-1600 nm thickness, which in turn is followed by another low-temperature AlN interlayer 115, onto which a third GaN layer 116 is then deposited. Onto this third GaN layer, in turn, a second masking layer 117 made of SiN is deposited. The second SiN masking layer 117 causes a reduction in the dislocation density in the subsequent fourth GaN layer 118. The four GaN layers 110, 114, 116 and 118 are n-doped. Doping is effected during growth by adding a suitable doping precursor.

A multi-quantum well structure is deposited on the fourth GaN layer 118. The choice of material and the exact layer structure of this multi-quantum well structure 120 are adjusted according to the desired wavelength of light emission. The parameters to be adjusted for this purpose, such as the layer stoichiometry and layer thickness, are known to a person skilled in the art. As is known, the band gap of a nitride semiconductor can be reduced in the direction of the band gap of indium nitride, starting with pure GaN, for example. By adding aluminium, the band gap is increased in the direction of the AlN value. In this way, light emission of a desired wavelength in the spectral range between red and ultraviolet may be set.

An injection barrier about 10-30 nm thick (not shown in FIG. 1) may be optionally provided on the multi-quantum well structure 120.

What is shown in the Figure, instead, is a covering layer 122 made of p-GaN and in direct contact with the multi-quantum well structure 120.

The above description related to an embodiment of a nitride semiconductor component according to the invention. It should be understood that, in the case of a different component such as a field-effect transistor, the layer structure details must be adjusted in detail in ways that are known per se.

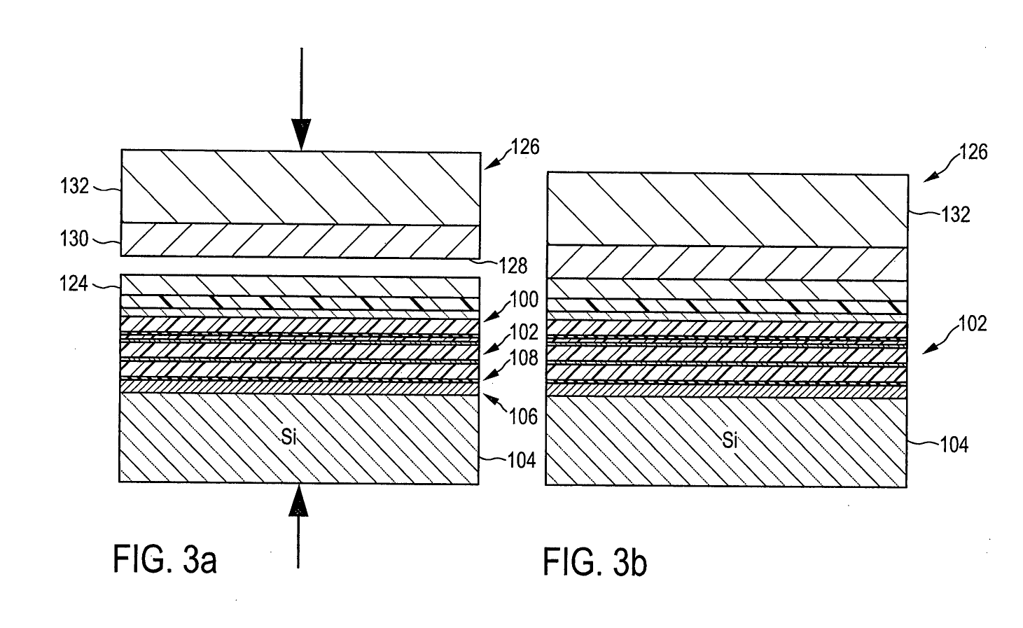

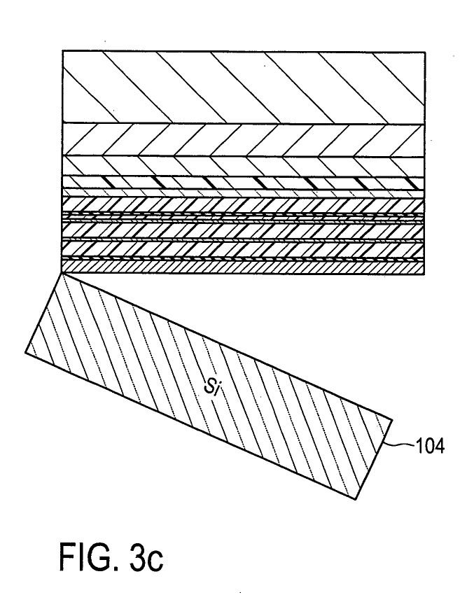

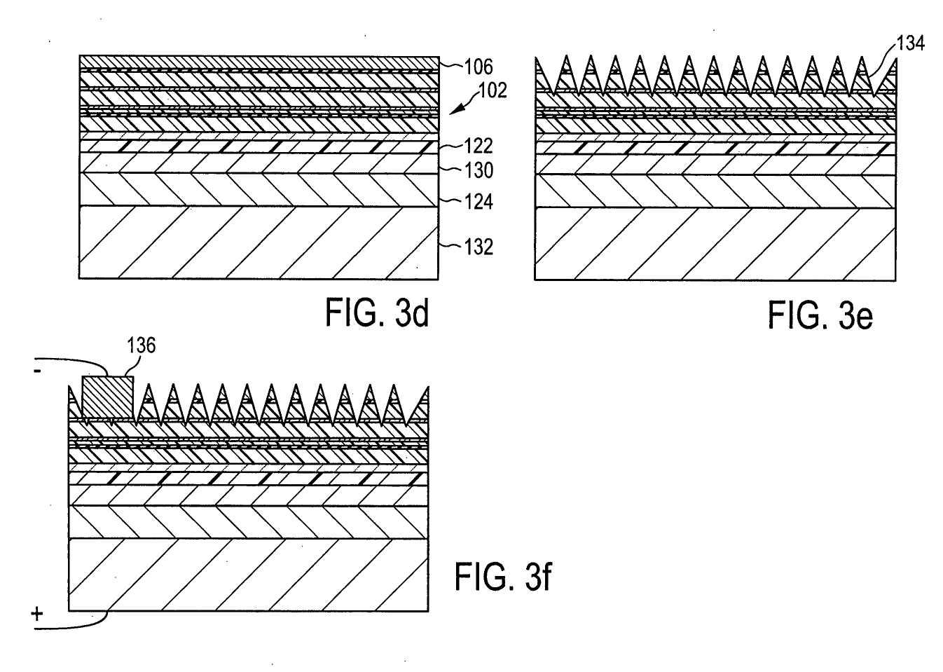

FIGS. 3a) to 3f) show different stages of the process for making a light-emitting diode from the nitride semiconductor component of FIG. 1. The process described here follows the production of the nitride semiconductor component of FIG. 1.

The nitride semiconductor component 100 is firstly subjected to surface metallisation. This is used for subsequent bonding to a substrate 126 and for improving the light extraction from the resultant component.

Substrate 126 is produced from copper or AlSi and has a metallised layer 130 on the one side 128 used for bonding. FIG. 3b) illustrates a stage of the process subsequent to bonding. Bonding is carried out at a temperature of 280° C. Using such a low temperature has the advantage that no additional stresses are caused by the thermal cycle during bonding.

The silicon wafer 104 is removed in a subsequent step. This is shown schematically in FIG. 3c). Silicon wafer 104 is removed by grinding and etching. Etching may be wet chemical or dry chemical etching. Such removal is significantly easier compared to the use of substrates with a (111) growth surface.

In this way, the structure illustrated in FIG. 3d) is produced, in which the seeding layer 106 formerly bonded to the silicon wafer now forms the upper side and the p-covering layer 122 is in direct contact with the metallised layer 124/130. In a subsequent step, the upper side is structured by etching. This etching, for example with KOH or H₃PO₄, results in the formation of pyramid-shaped structures that improve the light extraction from the component (FIG. 3e). Contact structure are then produced. The flux polarity of the LED is defined by providing a negatively poled contact 136 on the surface and a positively poled contact on the substrate (FIG. 3f).

The invention makes it possible to grow layers on large substrates, thus permitting either the production of large components or cost-efficient production of a large number of smaller components. The process described does not require any laser stripping commonly used in the case of sapphire substrates, and is therefore simpler and cheaper. Photolithographic steps are only necessary when producing the rear side contact and structuring prior to separation of the components.

1. A nitride semiconductor component having a Group III nitride layer structure which is deposited epitaxially on a substrate having a Group IV substrate surface made of a Group IV substrate material with a cubical crystal structure, characterised in that the Group IV substrate surface has an elementary cell with C2 symmetry when any surface reconstruction is ignored, but having a higher rotational symmetry than C2 symmetry, wherein immediately adjacent to the Group IV substrate surface the Group III nitride layer structure has a seeding layer made of either GaN or AlN or of a ternary or quarternary Al_{1-x-y}InₓGa_{y}N, where 0≦x, y<1 and x+y≦1.

2. The nitride semiconductor component according to claim 1, wherein the Group IV substrate surface is an {nm0} surface, where n, m are integers greater than zero.

3. The nitride semiconductor component of claim 1, wherein the Group IV substrate surface is a {nml} surface, where n, m are non-zero integers and l≧2.

4. The nitride semiconductor component of claim 1, wherein the Group IV substrate surface is a {110} surface of the silicon.

5. The nitride semiconductor component of claim 1, wherein the Group IV substrate surface is a {11l} surface of the silicon, where l≧2.

6. The nitride semiconductor component of claim 1, wherein the Group IV substrate surface is a {410}, {411} or {41l} surface of the silicon is, where l≧2.

7. The nitride semiconductor component of claim 1, having a buffer layer of Al_{1-x-y}InₓGa_{y}N, where 0≦x, y<1 and x+y≦1, immediately adjacent to the seeding layer.

8. A process for producing a nitride semiconductor component, comprising epitaxial deposition of a Group III nitride layer structure onto a Group IV substrate surface made of a Group IV substrate material with a cubical crystal structure, characterised in that the Group III nitride layer structure is deposited epitaxially on a Group IV substrate surface which for the purpose of conceptual definition, ignoring any surface reconstruction, has an elementary cell with C2 symmetry, but not with a higher rotational symmetry than C2 symmetry and that immediately adjacent to the Group IV substrate surface a seeding layer made of Al_{1-x-y}InₓGa_{y}N, where 0≦x, y<1 and x+y≦1, is epitaxially deposited.

9. The process of claim 8, comprising partially or wholly wet or dry chemical removal of the substrate after epitaxial deposition of the Group III nitride layer structure.

10. The process of claim 8, wherein the seeding layer is deposited by metalorganic vapour phase epitaxy, MOVPE, and wherein die seeding layer is epitaxially deposited with at least 90% of the total number of Group III atoms in the seeding layer being aluminium atoms.
